(19) United States
(12) Patent Application Publication
(10) Pub. No.: US 2014/0242374 A1
(43) Pub. Date: Aug. 28, 2014

(54) Porous Metal Coating

(71) Applicant: INFINEON TECHNOLOGIES AG, Neubiberg (DE)

(72) Inventors: Johann Strasser, Schierling (DE); Thomas Kunstmann, Laaber (DE); Manfred Frank, Nittendorf (DE); Werner Robl, Regensburg (DE); Maximilian Krug, Zeitlarn (DE); Simon Faiss, Regenstauf (DE); Matthias Mueller, Regensburg (DE)

(73) Assignee: INFINEON TECHNOLOGIES AG, Neubiberg (DE)

(21) Appl. No.: 13/774,624

(22) Filed: Feb. 22, 2013

(51) Int. Cl. H01L 23/14; B05D 7/00; C25D 7/12; B32B 3/26

(52) U.S. Cl. CPC H01L 23/14; B32B 3/26; B05D 7/52; C25D 7/12
USPC 428/307.7; 428/312.8; 428/307.3; 427/261; 427/248.1; 427/569; 118/715; 118/400; 118/723 R; 205/157; 204/242

(57) ABSTRACT

Various methods, apparatuses and devices relate to porous metal layers on a substrate which are three-dimensionally coated. In one embodiment, a porous metal layer is deposited over a substrate. The porous metal layer can be three-dimensionally coated with a coating material.

### TECHNICAL FIELD

The present application relates to coating of porous metal layers.

### BACKGROUND

In the manufacturing process of semiconductor devices, metal layers are deposited on substrates like semiconductor wafers. These metal layers are then structured to form, for example, interconnects, bonding pads, heat sinks or the like. Conventionally deposited metal layers, for example, copper layers, may, e.g., cause stress to the substrate or, e.g., exert a force on the substrate, e.g., due to thermal expansion, which may be undesirable in some circumstances. Similar problems may occur when depositing metal layers on other kinds of substrates in other processes than semiconductor device manufacturing processes.

In recent years, the use of porous metal layers has been investigated. Porous metal layers may for example be deposited by plasma-based deposition methods or other methods and may exhibit varying porosity depending for example on the conditions during deposition of the metal layer. Porosity in this respect refers to the percentage of metal layers being occupied by voids (“pores”), a high porosity layer having a higher percentage of its volume occupied by such voids than a layer with a lower porosity. Such porous metal layers may in some cases have favorable thermal and/or mechanical properties, for example, in terms of stress induced or forces exerted due to thermal expansion. However, integration of such porous metal layers in manufacturing processes, for example, of silicon-based devices constitutes an obstacle to be solved. For example, porous metal layers may have in some cases less favorable adhesive properties than conventional metal layers, or may have a reduced hardness.

### BRIEF DESCRIPTION OF THE DRAWINGS

FIG. 1 schematically shows an apparatus according to an embodiment;

FIG. 2 shows a flow chart illustrating a method according to an embodiment;

FIGS. 3-6 show cross-sectional electron microscopy images of devices according to some embodiments; and

FIG. 7 shows a schematic cross-sectional view of a device according to an embodiment.

### DETAILED DESCRIPTION OF ILLUSTRATIVE EMBODIMENTS

In the following, embodiments will be described in detail with reference to the attached drawings. It should be noted that these embodiments merely serve illustrative purposes and are not to be construed as limiting the scope of the present application in any way. For example, features from different embodiments may be combined with each other unless specifically noted otherwise. Furthermore, while embodiments are described as comprising a plurality of features or elements, this should not be construed as indicating that all those features or elements are necessary for implementing embodiments. For example, other embodiments may comprise fewer features or elements, or feature or elements of the described embodiments may be replaced with other features or other elements, for example, other features or other elements which perform essentially the same function as the features or elements they replace.

Various embodiments relate to depositing a porous metal layer on a substrate, for example, a semiconductor wafer or other substrate. In embodiments, the porous metal layer is then coated in a three-dimensional manner with a coating material. The coating material may comprise a material different from the porous metal layer, but may also comprise the same material, for example, comprise a corresponding non-porous metal layer. “A coating material” is to be construed that one or more coating materials may be used, which may be comprised in one or more coating layers.

Three-dimensional coating in this respect means that at least part of the surface of the pores or voids within the porous metal layer are coated, for example, at least 20% of the pore surfaces, at least 50% of the pore surfaces or at least 80% of the pore surfaces, and not just an outer surface of the porous metal layer. Detailed example for such coating layers will be explained later in more detail.

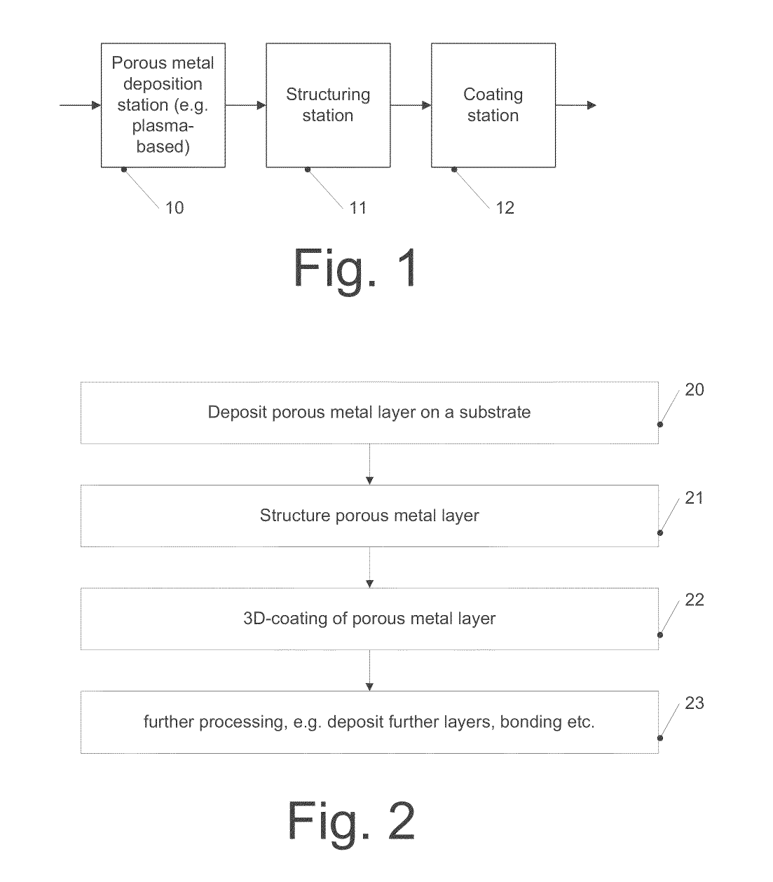

Turning now to the figures, in FIG. 1 a processing apparatus according to an embodiment is shown. The apparatus of FIG. 1 comprises a plurality of processing stations or devices in which substrates, for example, semiconductor wafers or other substrates, are successively processed. It should be noted that each station depicted may in some cases have several sub-stations to perform several process steps consecutively within one of the stations. Moreover, it should be noted that the apparatus of FIG. 1 may be part of a larger processing apparatus, i.e., additional conventional stations may be present which process the substrate before entering the apparatus of FIG. 1 and/or which process the substrate after leaving the apparatus of FIG. 1. In particular, the apparatus of FIG. 1 may be used to process already structured semiconductor wafers, for example, wafers where devices have been formed by processes like doping (for example, via ion implantation), growth of epitaxial layers, structuring of layers and the like. However, the apparatus of FIG. 1 may equally be used to process semiconductor wafers or other substrates which have not previously been processed, or processed substrates other than semiconductor wafers. Examples for another substrate type than semiconductor wafers include, for example, glass substrates and/or substrates for the manufacturing of solar devices. Also, the term “apparatus” as used herein is not to be construed as implying any specific spatial relationship between the components of the apparatus. For example, different stations shown in FIG. 1 may be located in different parts of a room or even in different rooms, with corresponding mechanisms to transfer substrates from one station to the next being provided. Likewise, different sub-stations of a station need not be located proximate to each other. Also, additional stations or devices may be employed between the stations shown.

In FIG. 1, in a porous metal deposition station 10 a porous metal layer is deposited on a substrate, for example, a semiconductor wafer like a silicon wafer or any other kind of substrate. The substrate may be unprocessed or previously processed. For example, semiconductor structures may be formed on the substrate. Also, in some embodiments prior to the deposition of the porous metal layer a seed layer made, for example, of the same metal as the porous metal may be deposited onto the substrate. Also, in some cases an etch stop layer may be deposited prior to depositing the porous metal layer. In other embodiments, the porous metal layer may be deposited onto a substrate where no specific layers have been deposited previously.

The porous metal layer deposited in porous metal deposition station 10 may, for example, be made of copper, or of a copper alloy comprising for example at least 50% copper, at least 80% copper or at least 90% copper. Additionally or alternatively, the porous metal layer may comprise any other suitable metal, for example, silver. In some embodiments, porous metal deposition station 10 is a plasma-based porous deposition station. In such a case, a plasma deposition may be used in which a plasma jet and/or an activated carrier gas and/or a particle stream are generated, for example, using a low temperature compared to processes like plasma/flame spraying and in which the speed of the activated particles is low compared to processes like plasma spraying or cold gas spraying. The particles to be deposited, in particular metal particles like copper particles, may be supplied in powder form to the plasma jet using, for example, a carrier gas.

For generating the plasma jet, for example a discharge between two electrodes may be used. To achieve this, for example, a voltage may be supplied to the electrodes, which are separated by a dielectric material. For example, the dielectric material may be an isolation pipe where one electrode is provided within the pipe and another electrode is provided outside the pipe.

In operation, in such an apparatus a glow discharge may result. By supplying a processing gas which streams through the device, which may be in the form of a tube, a plasma jet is generated which may be mixed with the carrier gas. The carrier gas as mentioned above may include the particles used for coating a surface of the substrate, i.e., particles to be deposited on the surface, in this case metal particles. In various embodiments, the mixing may be carried out in a reaction zone outside of the part of the device generating the plasma jet. In the reaction zone, energy of the plasma may be transferred to the carrier gas and/or the particles included in the carrier gas. For example, the particles included in the carrier gas may be activated by the mixing of the carrier gas with the plasma jet in the reaction zone such that, for example, a stream or jet of activated particles may be generated. In some embodiments, a plurality of reaction zones may be provided.

As this is a conventional technique for deposition of porous metals, it will not be described in greater detail here. Other techniques for depositing porous metal layers may be used as well.

The thickness of the deposited metal layer may, for example, be between 10 μm and 1000 μm, for example, between 50 μm and 600 μm.

Such porous metal layers may in some cases have favorable properties regarding stress compared to metal layers deposited for example by physical vapor deposition (PVD) or electrochemical deposition (ECD).

After the porous metals have been deposited in porous metal deposition station 10, the substrate in the embodiment of FIG. 1 is transferred to a structuring station 11 where the porous metal layer is structured. In other embodiments, structuring station 11 may be omitted, or the structuring station 11 may be provided downstream of a coating station 12 to be described later. In structuring station 11, the porous metal layer is structured. In some embodiments, for example, a mask may be provided on the porous metal layer, and the porous metal layer may subsequently be etched, for example, by wet chemical etching. In other embodiments, other structuring techniques, for example, chemical mechanical polishing (CMP), damascene technique and/or lift-off technique may be additionally or alternatively employed by structuring station 11.

After the porous metal layer has been structured, the substrate is transferred to coating station 12.

In coating station 12, a three-dimensional coating of the porous metal layer is employed. Three-dimensional coating in this case means that not only an outer surface of the porous metal layer is coated, but a surface within pores of the porous metal layer is at least partially coated, for example at least 20% of the surface, at least 50% of the surface or more. Such a coating of the pore surface may also be effected by filling the pores with the coating material.

Various techniques may be used to perform the three-dimensional coating. For example, the corresponding coating layer can be deposited from a gas phase, for example, by atomic layer deposition (ALD), chemical vapor deposition (CVD) or physical vapor deposition (PVD), from a liquid phase, for example by electrochemical deposition (ECD) or electroless deposition, and/or from a solid phase, for example, by sintering. However, these techniques serve only as examples, and other techniques may be used as well. Also, as already mentioned, the porous metal layer may be structured prior to the three-dimensional coating, for example, by structuring station 11, or may be unstructured. It should also be noted that also more than one coating layer may be used.

Various materials may be used for coating. For example, nickel phosphorous (NiP) or nickel molybdenum phosphorous (NiMoP), which in some embodiments may be deposited using an electroless deposition (eless deposition). In some embodiments, a one or more further layers may be deposited onto the NiP, for example, a palladium (Pd) layer, which in some embodiments may be followed by a gold (Au) layer. The thickness of such layers may be of the order of some micrometers or below, but is not restricted thereto. For example, a NiP layer of about 3 μm followed by a Pd layer of about 0.3 μm may be used. However, these numerical values are given only by way of example, and other layer thicknesses may be used as well. In other embodiments, for example, a silver tin alloy (AgSn) may be used. In still other embodiments, the same metal as the porous metal may be used. For example, a copper coating layer may be deposited on a porous copper layer by galvanic deposition. In still other embodiments, an organic film may be used as a coating.

Depending on the thickness and material of the coating layer, the electrical and/or mechanical properties of the porous metal may be influenced or adjusted, for example, tuned to have desired properties.

After leaving coating station 12, the substrates may be further processed. For example, further layers may be deposited, bonding may be performed, the porous metal layer may be structured in cases where structuring station 11 is omitted etc.

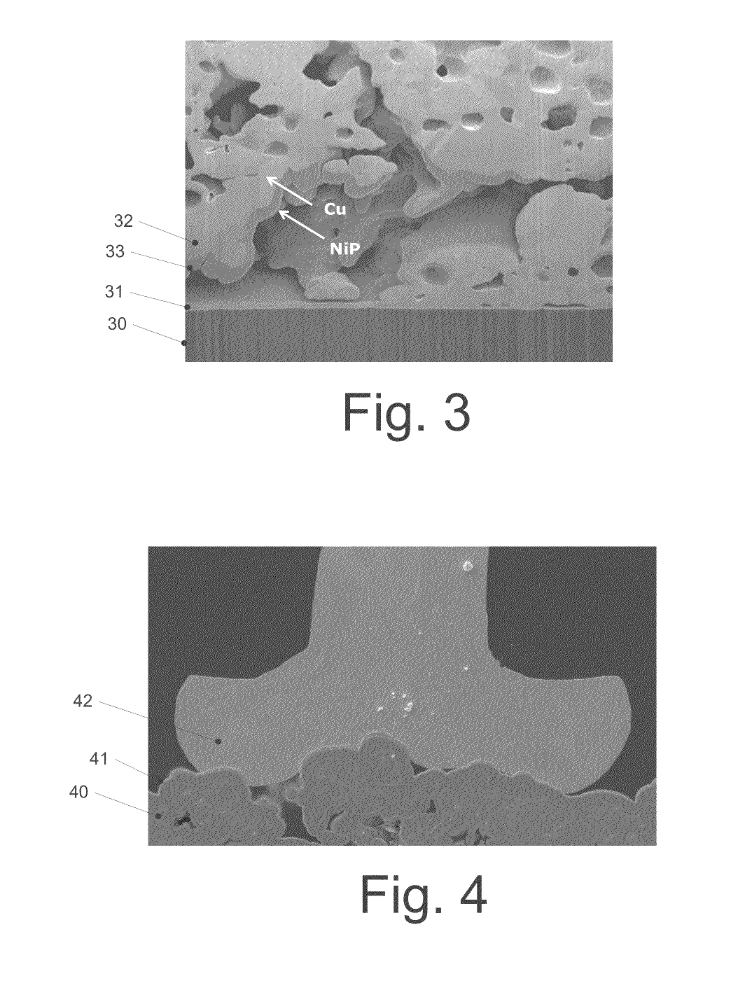

In FIG. 2, a flow chart illustrating a method according to an embodiment is shown. While the method of FIG. 2 is illustrated as a series of acts or events, it should be noted that the shown order of such acts or events is not to be construed as limiting, and the acts or events may also be performed in a different order. Also, some of the acts or events shown may be omitted, and/or additional acts or events may be provided.

At 20 in FIG. 2, a porous metal layer is deposited on a substrate. The substrate may, for example, be a semiconductor substrate like a silicon wafer, a glass substrate or any other suitable substrate. The porous metal layer may, for example, be made of copper, an alloy comprising copper or any suitable metal, for example, silver. In some embodiments, the porous metal layer may be deposited on a seed layer and/or etch stop layer provided on the substrate. In some embodiments, the substrate may be processed. In other embodiments, no additional layers are provided on the substrate.

The porous metal layer may, for example, be deposited using a plasma-based technique as described above or any other suitable technique. The porous metal layer may be deposited to a thickness between 10 μm and 1000 μm, for example, between 50 μm and 600 μm, and may have a porosity between 5% and 90%, for example, between 20% and 60%. However, in general depending on the application any desired porosity and thickness may be selected by adjusting processing conditions accordingly.

At 21, optionally the porous metal layer is structured, for example, by wet chemical etching, a lift-off technique, a CMP technique and/or a damascene technique. In other embodiments, this structuring may be omitted or performed later in the process, for example, after the actions described below with reference to 22.

At 22, a three-dimensional (3D) coating of the porous metal layer is performed. Three-dimensional coating as mentioned above implies that at least part of, for example, at least 20%, of the surface within pores of the porous metal layer is coated. Various techniques may be used for this three-dimensional coating, for example, ALD, CVD, PVD, ECD, electroless deposition, sintering or other techniques for depositing a coating layer from the gas phase, liquid phase and/or solid phase. Various coating materials or combinations thereof may be used to influences the electrical and/or mechanical properties of the porous metal layer in a desired manner. Examples for coating materials include metals like copper, metal alloys like a silver tin alloy or other materials like nickel phosphorous. In some embodiments, a conductive material is used to enable an electric contacting of the porous metal layer.

At 23, further processing of the substrate is performed, for example, deposition of further layers, bonding for contacting the porous metal layer, sawing of the substrate or other processing. In other embodiments, no further processing is performed.

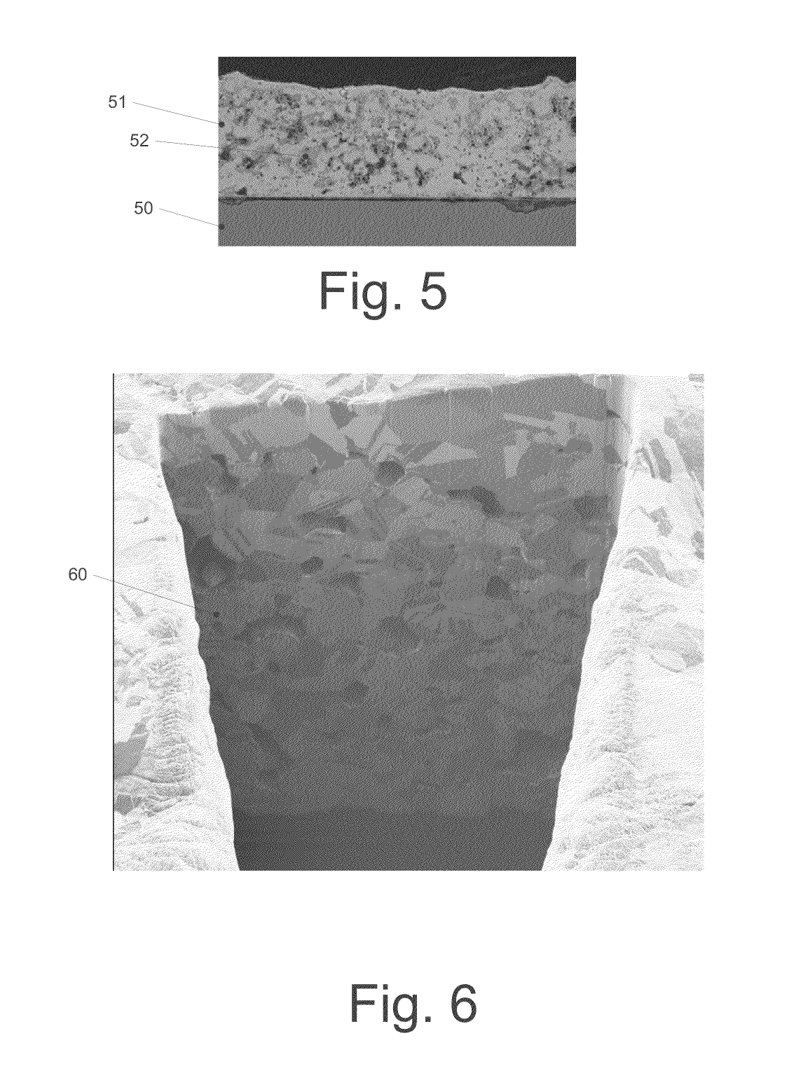

In the following, various embodiments of devices, comprising a substrate and a porous metal layer which is coated will be described with reference to FIGS. 3-7. FIGS. 3-6 show cross-sectional electron microscopy images of corresponding structures. While specific materials and structures are shown and described, in other embodiments other materials may be used, or other structures may be formed. For example, while in the example shown a porous copper layer deposited on a silicon substrate is used as an example, in other embodiments other substrate materials or metals may be used.

In FIG. 3, a porous metal layer, in this case a copper layer 32, is deposited on a silicon substrate 30 provided with a seed layer 31. In the example shown, seed layer 31 is also made of copper, although other materials may be used as well as long as the deposition of the porous copper layer 32 on seed layer 31 is possible.

In the embodiment shown, porous metal layer 32 is three-dimensionally coated with a nickel phosphorous (NiP) layer 33, which may, for example, by deposited by electroless (eless) deposition techniques, followed by a palladium (Pd) layer. In other embodiments, additionally a gold layer may be provided. In still other embodiments, nickel molybdenum phosphorous (NiMoP) may be used instead of NiP.

Such copper layers provide a good adhesion to bonding. For example, in FIG. 4 a porous copper layer 40 coated with a NiP layer 41 similar to the situation of FIG. 3 is shown, wherein a bond wire 42 is bonded to the coated porous metal layer.

In FIG. 5, a further embodiment is shown. Also, in this embodiment, a porous copper layer 51 is deposited on a silicon substrate 50. Porous metal layer 51 in the embodiment of FIG. 5 is three-dimensionally coated by a silver tin alloy. In the embodiment of FIG. 5, the coating has been performed by sintering silver tin solder on the porous copper.

A further embodiment is shown in FIG. 6. Here, at 60, a galvanic deposition, i.e., an electrochemical deposition, of a copper coating layer on a porous copper layer has been performed.

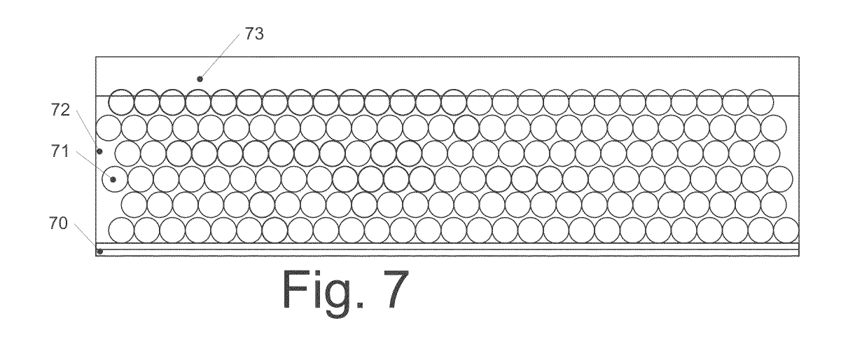

A further embodiment of a structure is schematically shown in cross section in FIG. 7. Here, a porous metal layer 71 deposited on a substrate 70 is symbolized by circles, the gaps between the circles representing pores of the porous metal layer. This representation is to be seen as schematic only, and the porous metal layer can have any irregular form, for example, as shown in FIGS. 3-6. In the embodiment of FIG. 7, porous metal layer 71 is coated with an organic film 72 capped with a conductive layer 73, for example, a NiP/Pd/Au layer or any other conductive layer. Conductive layer 73 electrically contacts porous metal layer 71.

As can be seen from the various examples and embodiments described above, various possibilities exist for three-dimensionally coating a porous metal layer in various embodiments. The various examples given are not to be construed as limiting, and other coating materials and/or other coating techniques may be used as well.

What is claimed is:

1. A method, comprising:
providing a substrate,
depositing a porous metal layer on said substrate, and
three-dimensionally coating said porous metal layer with a coating material.

2. The method of claim 1, wherein said three-dimensionally coating comprises coating at least 20% of a surface within pores of the porous metal layers.

3. The method of claim 1, wherein said three-dimensionally coating comprises depositing a coating layer from at least one of a gas phase, a liquid phase or a solid phase.

4. The method of claim 1, wherein said three-dimensionally coating comprises performing at least one of atomic layer deposition, chemical vapor deposition, physical vapor deposition, electrochemical deposition, electroless deposition or sintering.

5. The method of claim 1, wherein said coating material comprises an electrically conductive material.

6. The method of claim 1, wherein said coating material comprises at least one of nickel phosphorous, nickel molybdenum phosphorous or a metal.

7. The method of claim 1, wherein said three-dimensionally coating comprises depositing at least two coating layers successively.

8. The method of claim 1, wherein said depositing a porous metal comprises performing a plasma-based deposition.

9. The method of claim 1, further comprising structuring said porous metal layer prior to said three-dimensionally coating.

10. An apparatus, comprising:
a porous metal deposition station to deposit a porous metal layer on a substrate, and
a coating station to three-dimensionally coat said porous metal layer.

11. The apparatus of claim 10, further comprising a structuring station to structure said porous metal layer.

12. The apparatus of claim 11, wherein said structuring station is to receive substrates from said porous metal deposition station and to provide substrates to said coating station.

13. The apparatus of claim 10, wherein said coating station is configured to perform one or more of an atomic layer deposition, a chemical vapor deposition, a physical vapor deposition, an electrochemical deposition, an electroless deposition or a sintering.

14. The apparatus of claim 10, wherein said porous metal deposition comprises a plasma-based porous metal deposition station.

15. A device, comprising:
a substrate,
a porous metal layer, and
a coating layer three-dimensionally coating the porous metal layer.

16. The device of claim 15, wherein said coating layer covers at least 20% of a surface within pores of the porous metal layer.

17. The device of claim 16, wherein said coating layer covers at least 50% of said surface within said pores of said porous metal layer.

18. The device of claim 15, wherein said porous metal comprises copper.

19. The device of claim 15, wherein said coating layer is electrically conducting.

20. The device of claim 15, further comprising a further coating layer coating said coating layer.

21. The device of claim 15, wherein said coating layer comprises at least one of nickel phosphorous, nickel phosphorous molybdenum, an organic material, a silver tin alloy or copper.

22. The device of claim 15, wherein said substrate comprises a semiconductor wafer.

23. The device of claim 22, wherein said semiconductor wafer comprises silicon.

24. The device of claim 15, further comprising a bond wire fixed to said porous metal layer.

25. The device of claim 15, wherein said porous metal layer is structured.
